(19) United States
(12) Patent Application Publication
(10) Pub. No.: US 2005/0142467 A1
(43) Pub. Date: Jun. 30, 2005

(54) Color filter manufacturing method, solid state color image sensing apparatus and camera having color filter

(76) Inventors: Tomoko Komatsu, Kyotanabe-shi (JP); Mitsuru Harada, Katano-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/016,747

(22) Filed: Dec. 21, 2004

(30) Foreign Application Priority Data
Dec. 26, 2003 (JP) 2003-433871

(51) Int. Cl. G02B 5/20; H01L 27/14

(52) U.S. Cl. 430/7; 257/440

(57) ABSTRACT

A color filter manufacturing method of the present invention including: applying a negative type dye color photoresist; applying an oxygen permeation prevention film on the negative type dye color photoresist; exposing a predetermined part of the oxygen permeation prevention film from above; and forming, on the predetermined part, a color filter made from the negative type dye color photoresist by removing, using a developer, at least a part of the negative type dye color photoresist formed outside the predetermined part and permeation prevention film.

### BACKGROUND OF THE INVENTION

(1) Field of the Invention

The present invention relates to a color filter manufacturing method using a negative type dye color photoresist, and a solid state color image sensing apparatus and a camera having the color filters.

(2) Description of the Related Art

As a method for manufacturing a color filer mounted on an image sensor, a dyeing method, an electrodepositing method, a printing method and a dye dispersion method are used at present.

The dyeing method that is one of the above-mentioned methods is for manufacturing color filters by dyeing a substrate made of natural resin such as gelatin, glue, casein or the like or synthetic resin such as amine-modified polyvinyl alcohol using an acid dye or the like. This method has the advantages of (i) excellent spectral characteristics and (ii) color purity, but it also has the disadvantages that (i) color shading is likely to occur because it is difficult to evenly control dyeing process and the adhesion of a dye in the manufacturing process and (ii) the dyeing processing is made complicated because an additional process of protection against dyeing becomes needed in the dyeing process.

In the technique disclosed in the Japanese Laid-Open Patent application No. 2000-112134 publication, the oxygen barrier film should include, as a material, at least a water-soluble resin having an oxygen barrier property and a light absorbent whose light absorption wave range matches, at least in part, the light absorption wave range of the polymerization initiator included in the photosensitive resin layer. Further, in the technique, the oxygen barrier film made of the above-mentioned materials for forming a pattern is formed on a photosensitive resin layer that includes at least a monomer of free-radical-initiated polymerization type and a polymerization initiator, the photosensitive resin layer is exposed in a predetermined pattern via the oxygen barrier film, in a state that its photosensitivity is adjusted to a predetermined level by selecting a suitable light absorbent to be included in the oxygen barrier film and adjusting its amount in order to control the number of radicals to be generated in the photosensitive resin layer, and then development is performed so as to form a pattern.

In this way, the amount of light absorbed by the polymerization initiator included in the photosensitive resin layer is adjusted by the light absorbent included in the material of the oxygen barrier film, which enables arbitrary controlling the sensitivity (the number of radicals to be generated) in the exposure part of the photosensitive resin layer. Further, the water-soluble resin having an oxygen barrier property acts for preventing deactivation by the oxygen of radicals generated in the exposure part of the photosensitive resin layer, a proper number of radicals generated in the exposure part are polymerized without being dispersed, and the oxygen barrier film is removed in the development process.

However, in the case where the oxygen barrier film is formed on the photosensitive resin layer like mentioned above, there is a problem that it becomes difficult to control the line width of the pattern because the photosensitivity (the number of radicals) of the photosensitive resin layer is too many. Also, there is another problem that the resolution of a fine pattern decreases because the radicals generated in the exposure part disperse to an unexposed part. Therefore, in the case of using the oxygen barrier film, there is a need to select a new photosensitive material in order to make the photosensitivity suitable, which causes a new problem that available photosensitive resin composition become more limited.

Also, in the technique disclosed in the Japanese Laid-Open Patent application No. 2002-323762 publication, a photosensitive resin composition made of a polymerization initiator including an O-acyloxime base and a dye are mixed and melted, and the resulting negative type color photosensitive composition is used in order to manufacture color filters having the resolution, form, heat-photoresistance, light-photoresistance and spectral characteristic that are excellent.

This negative type color photosensitive composition is not susceptible to oxygen inhibition when light polymerization initiator including O-acyloxime starts polymerization, which makes it possible to form color filters having an excellent resolution and few resin embossing impressions and little dye bleeding in forming color filters mounted on, for example, a liquid crystal display and a charge-coupled device.

Also, in the technique disclosed in the following document 1, a negative type dye color photoresist is used as a color photoresist and an excellent property of the negative type dye color photoresist is obtained. Note that no detailed photoresist composition and the like are disclosed.

Document 1: Horiguchi, Kitaori, Mangyou, Katou, “Development of the dye dissolved negative photoresist for color”, RadTech Asia'03,p. 589-592

However, as explained later, the above technique has a problem that the spectral characteristic that is sufficient to the miniaturization of color filters accompanied by the miniaturization of image sensors.

In other words, in the case where the size of a unit pixel is miniaturized to 1 to 5 μm, in the color filter manufacturing process where a negative type dye color photoresist is formed, exposure is performed from above, and the negative type dye color photoresist in a predetermined part is removed using the developer, the dye becomes thinner especially in the part near the peripheral part of the predetermined part because the developer touches the negative type dye color photoresist from every direction. Consequently, sufficient spectrum characteristics are not obtained because the internal area is too small to keep sufficient amount of dye in the case where the negative type dye color photoresist is very small, while more sufficient spectral characteristic can be obtained by a dye included in the internal part except the peripheral part in the case where the negative type dye color photoresist is not very small.

As a preventive measure of this problem, there is a method of thickening the film of the negative type dye color photoresist. However, thickening the film causes problems such as the deterioration of the photosensitive property, the occurrence of color mixture and the occurrence of shading of the image sensor in the case of using oblique incident light.

### SUMMARY OF THE INVENTION

A primal object of the present invention is to provide (i) a manufacturing method of color filters that can prevent the dye from becoming thinner in very small cells of an image sensor and obtain a necessary spectral dispersion and (ii) a solid state color image sensing apparatus and a camera having the color filters.

In order to achieve the above object, the color filter manufacturing method in the present invention including: applying a negative type dye color photoresist; applying an oxygen permeation prevention film on the negative type dye color photoresist; exposing a predetermined part of the oxygen permeation prevention film from above; and forming, on the predetermined part, a color filter made from the negative type dye color photoresist by removing, using a developer, at least a part of the negative type dye color photoresist formed outside the predetermined part and permeation prevention film.

In this way, forming the oxygen permeation prevention film on the negative type dye color photoresist makes it possible to improve the exposure sensitivity of the same and accelerate its cure. This enables preventing the dye from becoming thinner.

Further, in a first aspect of the color filter manufacturing method of the present invention, the oxygen permeation prevention film is water-soluble.

This eliminates the necessity of using a plurality of solutions, which simplifies the manufacturing processing of color filters.

Further, in a second aspect of the color filter manufacturing method of the present invention, the oxygen permeation prevention film is photosensitive.

This practically prevents the dye from becoming thinner even in the case where the developer touches the negative type dye color photoresist because the oxygen permeation prevention film is sufficiently cured. In addition, it is possible to prevent the dye from becoming thinner more efficiently by keeping the oxygen permeation prevention film instead of removing it using the developer.

Further, in a third aspect of the color filter manufacturing method of the present invention, the oxygen permeation prevention film allows permeation of visible light.

This does not badly affect the light in the permeation wavelength of the color filters.

Further, in a third and fourth aspects of the color filter manufacturing method of the present invention, a thickness of the oxygen permeation prevention film is within a range of 0.1 nm to 1 μm.

This enables sliming down the image sensor even in the case of keeping the oxygen permeation prevention film instead of removing it using the developer.

Further, in a third aspect of the color filter manufacturing method of the present invention, the oxygen permeation prevention film allows permeation of ultraviolet rays.

This enables performing the exposure processing efficiently.

Further, a solid state color image sensing apparatus that has a color filter manufactured using a color filter manufacturing method including: applying a negative type dye color photoresist; applying an oxygen permeation prevention film on the negative type dye color photoresist; exposing a predetermined part of the oxygen permeation prevention film from above; and forming, on the predetermined part, a color filter made from the negative type dye color photoresist by removing, using a developer, at least a part of the negative type dye color photoresist formed outside the predetermined part and permeation prevention film.

Further, the camera in the present invention has the solid state color image sensing apparatus in the present invention.

This enables realizing a solid state color image sensing apparatus having excellent color characteristics and a camera having the same.

As mentioned above, in the manufacturing method of color filters in the present invention, forming the oxygen permeation prevention film on the negative type dye color photoresist improves the exposure sensitivity of the same and accelerates the cure. This enables preventing the dye from becoming thinner.

Further, a high-sensitive exposure in very small cells can be realized and spectral characters necessary for the color filters of the image sensor can be evenly obtained.

### Further Information About Technical Background to This Application

The disclosure of Japanese Patent Application No. 2003-433871 filed on Dec. 26th, 2003 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A to 1D are a diagram for explaining a manufacturing method of color filters in a first embodiment of the present invention;

FIG. 2 is a section view of a pixel in the solid state color image sensing apparatus in the first embodiment;

FIG. 3 is a diagram for explaining a manufacturing method of color filters in a second embodiment of the present invention;

FIG. 4 is a section view of a pixel in the solid state color image sensing apparatus in a second embodiment; and

FIG. 5 is a diagram showing the spectral character of the color filters in the present invention.

### DESCRIPTION OF THE PREFERRED EMBODIMENT(S)

Embodiments of the present invention will be explained below with reference to figures.

(First Embodiment)

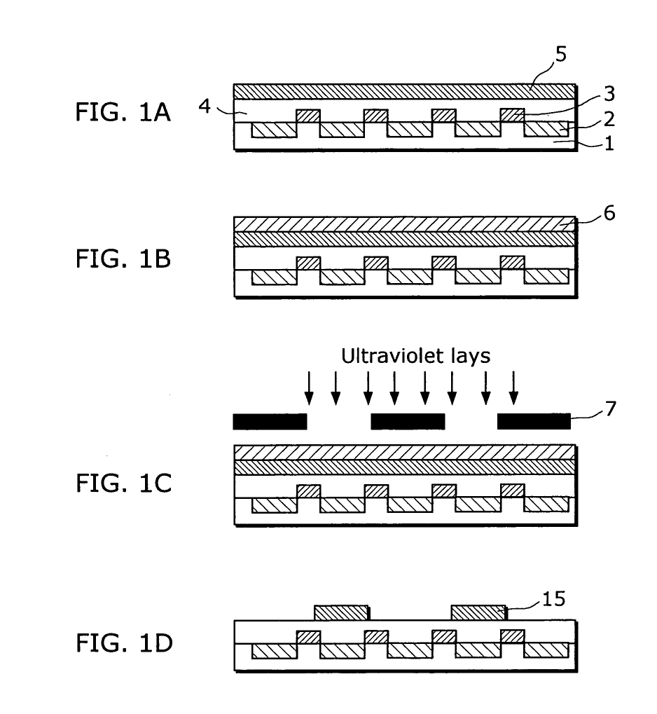

FIG. 1A to 1D are a diagram for explaining the manufacturing method of a color filter in the first embodiment of the present invention. As shown in FIG. 1A, a layer 3 including wires and the like is formed on the semiconductor substrate 1 where a light receiving part 2 is formed avoiding the opening of the light receiving part 2. Further, a flat layer 4 is formed on it. After that, the negative type dye color photoresist 5 is formed on the flat layer 4. Next, as shown in FIG. 1B, an oxygen permeation prevention film 6 is formed on the negative type dye color photoresist 5. Further, a pre-bake (heating process) is performed for 100 seconds at 80° C. Next, as shown in FIG. 1C, a pattern is formed by exposure of ultraviolet ray radiation via a photo mask 7 that determines the area for forming the color filters, perform development using an alkaline developer, and forms a color photoresist pattern. At that time, the oxygen permeation prevention film 6 on the pattern is also removed using the alkaline developer. In this way, as shown in FIG. 1D, a color filter 15 is formed on a predetermined position.

Further, a predetermined color filter is formed on each pixel by repeating the processes likewise shown in FIG. 1A to FIG. 1D using another photo mask that determines the parts for forming other kinds of color filters. After that, a micro lens is formed on each of the color filters so as to complete a solid state color image sensing apparatus.

As the negative type dye color photoresist 5, a dye photoresist of Nippon Kayaku Co. LTD disclosed in “RadTech Asia'03” held by the RadTech association is used.

In this way, as oxygen supply to the negative type dye color photoresist 5 is stopped by forming the oxygen permeation prevention film 6 on the negative type dye color photoresist 5, polymerization is more accelerated than in the related art, and thus the crosslink density increases. Therefore, it becomes possible to prevent the dye from becoming thinner caused by a developer, which enables obtaining a desired spectral dispersion.

The oxygen permeation prevention film 6 may be made of a water-soluble or a water-insoluble material. Available water-soluble materials are: water-soluble polyvinyl alcohol; butyral; polyethylene oxide; water-soluble cellulose; fluorine resins or the like. In this way, the use of a water-soluble material as the oxygen permeation prevention film 6 eliminates the necessity of using plural solutions, which simplifies the manufacturing process of the color filter 15.

On the other hand, available water-insoluble materials are: acrylic resins; epoxy resins or the like.

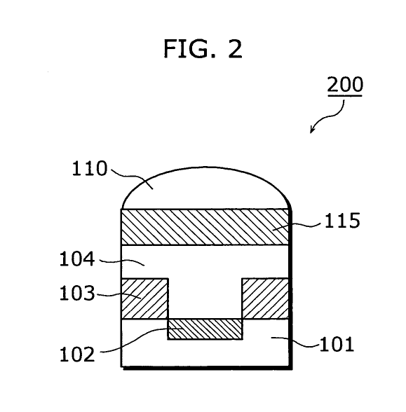

FIG. 2 is a section view of a pixel in the solid state color image sensing apparatus in the first embodiment of the present invention. In the solid state color image sensing apparatus 200, the light receiving part 102 is formed in the center of the upper part of the silicon substrate 101, the light receiving diode 102 being a p/n junction part that converts the incident light into electric charges. In addition, there is a charge-coupled device for permeating a signal of a light receiving diode, but it is omitted in the figure because it is simple. A layer 103 composed of multilayer wires, a light blocking film and the like is formed on the part where the light receiving diode 102 is not formed of the silicon substrate 101. Further, an acryl flat layer 104 is formed on the light receiving diode 102 and the layer 103 composed of multilayer wires and the like. The function of the flat layer 104 is flattening the surface that becomes uneven because of the charge-coupled devices and multilayer wires. A color filter layer 115 in the present invention is formed on the flat layer 104. A color filter layer 115 absorbs light of a predetermined wavelength region, which determines the color of the permeated light (wavelength). A micro lens 110 is formed on the color filter layer 115. The micro lens 110 gathers the light that passed through the color filter layer 115 and the light is launched into the light receiving diode 102.

In this way, forming the oxygen permeation prevention film on the negative type dye color photoresist makes it possible to improve the exposure sensitivity of the negative type dye color photoresist and accelerate the cure. This enables preventing the dye from becoming thinner.

Further, it becomes possible to realize a high-sensitive exposure in very small cells and obtain even spectral characteristics necessary for the color filters of the image sensor.

(Second Embodiment)

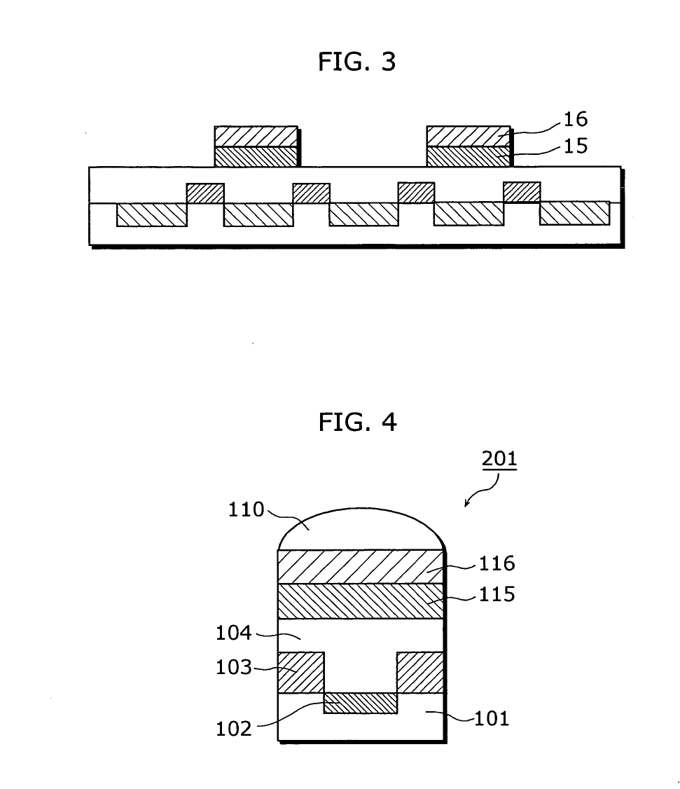

FIG. 3 is a diagram for explaining the manufacturing method of a color filter in the second embodiment of the present invention, and the color filter corresponds to the one shown in FIG. 1D in the explanation of the first embodiment. The manufacturing method is the same in appearance as the corresponding ones shown in FIG. 1A to FIG. 1C, but it differs from the ones in the first embodiment in that it uses an oxygen permeation prevention film 16 having a photosensitivity instead of the oxygen permeation prevention film 6. The color filter 15 can be manufactured in the same ultraviolet ray exposure process as the one performed in the first embodiment because the oxygen permeation prevention film 16 has a property of permeating ultraviolet rays.

As clear from the above explanation, the oxygen permeation prevention film 6 is not removed by exposure and development as shown in FIG. 1D in the explanation of the first embodiment, but the oxygen permeation prevention film 16 having photosensitivity is cured by exposure, is not removed by development and remains on the color filter 15 as shown in FIG. 3.

FIG. 4 is a section view of a pixel of a solid state color image sensing apparatus in the second embodiment of the present invention. The solid state color image sensing apparatus 201 that mounts the color filters manufactured using the color filter manufacturing method explained in FIG. 3 differs from the solid state color image sensing apparatus 200 shown in FIG. 2 in that it has an oxygen permeation prevention film 116 in the present invention on the color filter layer 115. The oxygen permeation prevention film 116 does not badly affect the light in the permeation wavelength region of the color filter layer 115 because it has a property of permeating visible light. In other words, the solid state color image sensing apparatus 201 is the same in function as the solid state color image sensing apparatus 200 in the first embodiment.

Also, the oxygen permeation prevention film 116 whose thickness is within a range of 0.1 nm to 1 μm does not affect the thickness of the entire solid state color image sensing apparatus 201, and thus it is possible to form a thin image sensor.

As the oxygen permeation prevention film 116 is sufficiently cured by exposure, the color of the negative type dye color photoresist rarely becomes thinner even in the case where a developer touches the color photoresist. Therefore, keeping the oxygen permeation prevention film 116 without removing it by a developer enables preventing the dye from becoming thinner in the negative type dye color photoresist more efficiently. Note that, the material of the oxygen permeation prevention film 116 having a photosensitive function may be acryl or epoxy resin.

(Third Embodiment)

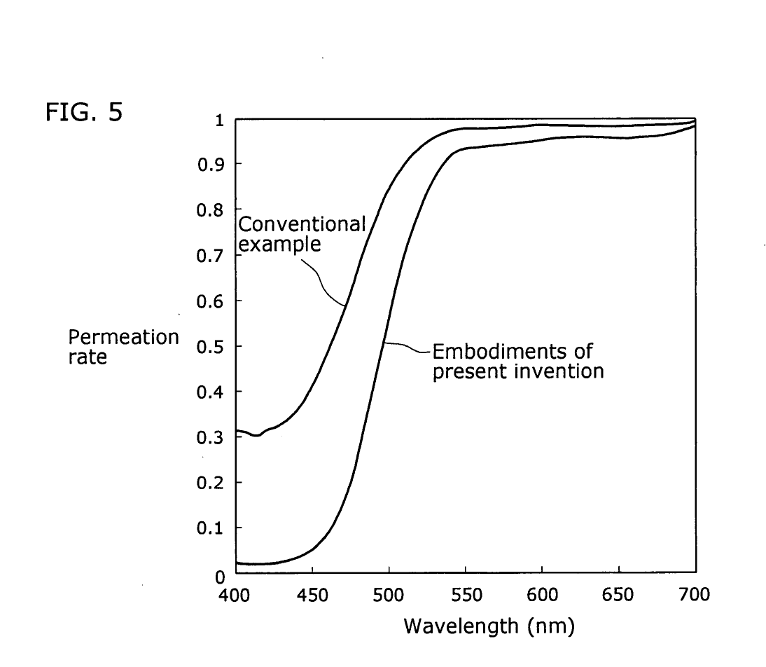

FIG. 5 is a diagram showing the spectral characteristics of a color filter for yellow whose size is about 1 μm in the present invention. The conventional color filter for yellow has a permeation rate of 0.3 in the wavelength around 400 nm, but the color filter for yellow in the present invention achieves a permeation rate that is far below 0.1. Further, the conventional color filter for yellow has a permeation rate of 0.8 in the wavelength around 500 nm, but the color filter for yellow in the present invention achieves a permeation rate of approximately 0.5.

In this way, with the color filter in the present invention, it is possible to realize a high-sensitive exposure in very small cells, and it is possible to obtain even spectral characteristics necessary for color filters in an image sensor.

Also, a camera that uses a solid state color image sensing apparatus mounting color filters manufactured using the color filter manufacturing method in the present invention has excellent color characteristics.

Explanations made up to this point are based on embodiments, but applications of the present invention are not limited to these embodiments.

For example, the temperature condition may be 50 to 150° C. in the pre-bake process, and the time may be 30 to 300 seconds. Also, the pre-bake is performed after the oxygen permeation prevention film 6 is formed in the first embodiment, but a pre-bake may be performed not only after a negative type dye color photoresist 5 is formed but also the oxygen permeation prevention film 6 is formed because the object of the pre-bake is solvent volatilization. Also, the oxygen permeation prevention film 6 does not need to perfectly block oxygen, in other words, it should block oxygen to some degree.

Also, it is desirable that the oxygen permeation prevention film 6 have a high permeation rate in the exposure wavelength for forming a pattern, but it does not need to have a property of permeating ultraviolet rays 100%. Also, ultraviolet rays used in the exposure process may be i-line, g-line, h-line or a mixture of these listed lines. Also, an ultraviolet ray having another wavelength or an electron ray may be used.

Further, subtractive complementary colors or additive primary colors may be used as dyes.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The color filters in the present invention are industrially practical because they are applicable for color filters in the sensor part of a CCD, a MOS sensor or the like or fine color filters having a severe spectral sensitivity property, and further, they are applicable for solid state color image sensing apparatuses mounted on digital video cameras, digital still cameras, mobile phones having a camera or the like.

1. A color filter manufacturing method comprising:
applying a negative type dye color photoresist;
applying an oxygen permeation prevention film on the negative type dye color photoresist;
exposing a predetermined part of the oxygen permeation prevention film from above; and
forming, on the predetermined part, a color filter made from the negative type dye color photoresist by removing, using a developer, at least a part of the negative type dye color photoresist formed outside the predetermined part and permeation prevention film.

2. The color filter manufacturing method according to claim 1,
wherein the oxygen permeation prevention film is water-soluble.

3. The color filter manufacturing method according to claim 2,
wherein the oxygen permeation prevention film is photosensitive.

4. The color filter manufacturing method according to claim 3,
wherein the oxygen permeation prevention film allows permeation of visible light.

5. The color filter manufacturing method according to claim 4,
wherein a thickness of the oxygen permeation prevention film is within a range of 0.1 nm to 1 μm.

6. The color filter manufacturing method according to claim 3,
wherein a thickness of the oxygen permeation prevention film is within a range of 0.1 nm to 1 μm.

7. The color filter manufacturing method according to claim 1,
wherein the oxygen permeation prevention film is photosensitive.

8. The color filter manufacturing method according to claim 7,
wherein the oxygen permeation prevention film allows permeation of visible light.

9. The color filter manufacturing method according to claim 8,
wherein a thickness of the oxygen permeation prevention film is within a range of 0.1 nm to 1 μm.

10. The color filter manufacturing method according to claim 7,
wherein a thickness of the oxygen permeation prevention film is within a range of 0.1 nm to 1 μm.

11. The color filter manufacturing method according to claim 3,
wherein the oxygen permeation prevention film allows permeation of ultraviolet rays.

12. The color filter manufacturing method according to claim 11,
wherein the oxygen permeation prevention film is water-soluble.

13. The color filter manufacturing method according to claim 11,
wherein the oxygen permeation prevention film is photosensitive.

14. The color filter manufacturing method according to claim 13,
wherein the oxygen permeation prevention film allows the permeation of visible light.

15. The color filter manufacturing method according to claim 14,
wherein a thickness of the oxygen permeation prevention film is within a range of 0.1 nm to 1 μm.

16. A solid state color image sensing apparatus, comprising
a color filter manufactured using a color filter manufacturing method including: applying a negative type dye color photoresist; applying an oxygen permeation prevention film on the negative type dye color photoresist; exposing a predetermined part of the oxygen permeation prevention film from above; and forming, on the predetermined part, a color filter made from the negative type dye color photoresist by removing, using a developer, at least a part of the negative type dye color photoresist formed outside the predetermined part and permeation prevention film.

17. The solid state color image sensing apparatus according to claim 16, further comprising
an oxygen permeation prevention film on a color filter.

18. A camera comprising
a solid state color image sensing apparatus further comprising an oxygen permeation prevention film on a color filter.
